(19) United States
(12) Patent Application Publication
(10) Pub. No.: US 2013/0243945 A1
(43) Pub. Date: Sep. 19, 2013

(54) METHOD OF MANUFACTURING CONDUCTIVE FILM ROLL

(71) Applicant: NITTO DENKO CORPORATION, Osaka (JP)

(72) Inventors: Nozomi Fujino, Ibaraki-shi (JP); Hiroyuki Takao, Ibaraki-shi (JP); Kuniaki Ishibashi, Ibaraki-shi (JP)

(73) Assignee: NITTO DENKO CORPORATION, Osaka (JP)

(21) Appl. No.: 13/771,772

(22) Filed: Feb. 20, 2013

(30) Foreign Application Priority Data
Mar. 13, 2012 (JP) 2012-055995

(51) Int. Cl. C23C 14/14

(52) U.S. Cl. CPC C23C 14/14
USPC 427/125; 427/123

(57) ABSTRACT

A method of manufacturing a conductive film roll includes a first step of transporting a film base having an elongated shape while laminating a first transparent conductor layer, a first metal layer and a metal oxide membrane layer by sputtering on a first face side of the film base to form a first laminated body, a second step of feeding the film base, to a second film formation roll without being wound up into a roll, transporting the film base while making the metal oxide membrane layer of the first laminated body into contact with the second film formation roll, and sequentially laminating a second transparent conductor layer and a second metal layer by sputtering on a second face side of the film base to form a second laminated body, and a third step of winding up the second laminated body into a roll.

### CROSS REFERENCE TO RELATED APPLICATIONS

This application claims the benefit of Japanese Patent Application No. 2012-055995, filed Mar. 13, 2012, which is hereby incorporated by reference herein in its entirety.

### BACKGROUND OF INVENTION

1. Field of the Invention

The invention relates to a method of manufacturing a roll of conductive film applicable to an input display unit capable of inputting information by a touch of a finger, a stylus pen, or the like.

2. Background of the Invention

In the related art, a conductive film including a transparent conductor layer formed on either face of a film base and a metal layer formed on a surface of each transparent conductor layer is known (Japanese Laid-Open Patent Publication No. 2011-060146). When employing such a conductive film for a touch sensor, for example, a narrow bezel can be achieved by processing the metal layer and forming a wiring at an outer peripheral portion of a touch input area.

However, with such a conductive film of the related art, when the film is wound up, there is a problem that adjacent film surfaces may be bonded to each other. When the film surfaces bonded to each other are peeled apart, flaws may be produced in the transparent conductor layer in the film and may cause degradation of quality.

### SUMMARY OF INVENTION

It is an object of the invention to provide a method of manufacturing a conductive film roll in which adjacent film surfaces are not bonded to each other and can maintain a high quality.

To achieve the above mentioned object, a method of manufacturing a conductive film roll, includes a first step of transporting a film base having an elongated shape while making it into contact with a first film formation roll and sequentially laminating a first transparent conductor layer, a first metal layer and a metal oxide membrane layer by sputtering on a first face side of the film base to form a first laminated body, a second step of feeding the film base, on which the first laminated body is formed, to a second film formation roll without being wound up into a roll, transporting the film base while making the metal oxide membrane layer of the first laminated body into contact with the second film formation roll, and sequentially laminating a second transparent conductor layer and a second metal layer by sputtering on a second face side of the film base on which the first laminated body is not formed to form a second laminated body, and a third step of winding up the second laminated body into a roll.

Preferably, in the first step, the metal oxide membrane layer having a thickness of 1 nm to 15 nm is formed.

Preferably, the first metal layer and the second metal layer are made of a material selected from a group consisting of copper, silver, aluminum, copper alloy, nickel alloy, titanium alloy and silver alloy.

Preferably, the metal oxide membrane layer is made of an oxide of a material selected from a group consisting of copper, silver, aluminum, copper alloy, nickel alloy, titanium alloy and silver alloy.

According to the present invention, a film base is transported while being made it into contact with a first film formation roll and sequentially laminating a first transparent conductor layer, a first metal layer and a metal oxide membrane layer by sputtering on a first face side of the film base to form a first laminated body. The film base, on which the first laminated body is formed, is fed to a second film formation roll without being wound up into a roll, and a second transparent conductor layer and a second metal layer are sequentially laminated by sputtering on a second face side of the film base on which the first laminated body is not formed to form a second laminated body. With this method, adjacent film surfaces can be prevented from being bonded to each other by pressure and a high quality can be maintained.

### BRIEF DESCRIPTION OF DRAWINGS

FIG. 1 is flow chart showing a method of manufacturing a conductive film roll according to an embodiment of the present invention.

FIG. 2 is a diagram schematically showing a sputtering apparatus in which the manufacturing method of FIG. 1 is employed.

FIG. 3 is a perspective view showing an exemplary conductive film roll manufactured with the sputtering apparatus of FIG. 2.

### DETAILED DESCRIPTION

Hereinafter, an embodiment of the invention will be described in detail with reference to the accompanying drawings.

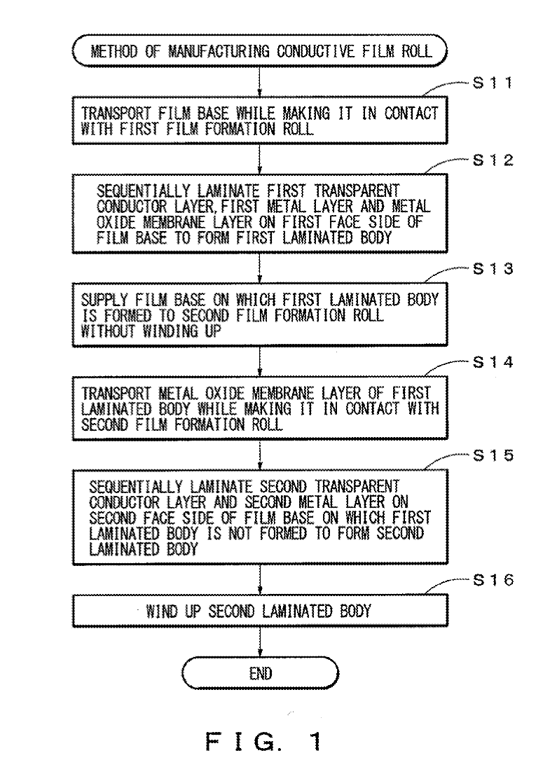

As shown in FIG. 1, a method of manufacturing of a conductive film roll of the present embodiment firstly transports a film base having an elongated shape while making it into contact with a first film formation roll (step S11), sequentially laminates a first transparent conductor layer, a first metal layer and a metal oxide membrane layer by sputtering on a first face side of the film base which is not in contact with the first film formation roll to form a first laminated body (step S12). Then, the film base, on which the first laminated body is formed, is fed to a second film formation roll without winding it up (step S13), and transported while making the metal oxide membrane layer of the first laminated body into contact with the second film formation roll (step S14), and a second transparent conductor layer and a second metal layer are sequentially laminated by sputtering, on a second face side of the film base on which the first laminated body is not formed, to form a second laminated body (step S15). Then, the film base (conductive film) on which the first and second laminated bodies are formed is wound up (step S16).

Since the conductive film roll obtained by such a manufacturing method has a metal oxide membrane layer on a side of the first metal layer opposite to the first transparent conductor layer, there is an advantageous effect that bonding does not occur even if a slip sheet is not inserted between conductive film surfaces when winding up. This is presumed to be because, when winding up the conductive film into a roll, with the metal oxide membrane layer without free electrons being interposed between the first copper layer and the second copper layer, which are adjacent to each other, metallic bonding between the first copper layer and the second copper layer can be prevented.

Further, with such a manufacturing method, since the first laminated body obtained from step S12 is fed to the second film formation roll without being wound up and steps S12 to S15 can be carried out continuously, there is a further effect that a productivity of the conductive film roll is increased as compared to a case where each step is carried out separately. In addition, since steps S11 to S16 are performed continuously, there is also an effect that contaminants are less likely to enter between each layer and thus a conductive film roll with reduced defects and having an improved quality can be obtained.

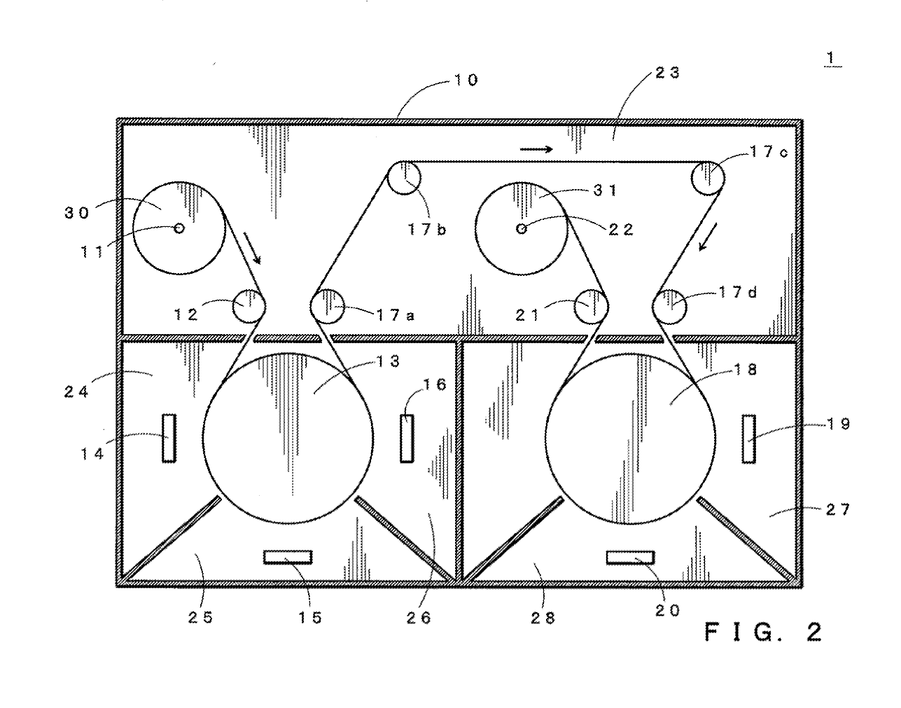

The manufacturing method is preferably carried out with a sputtering apparatus of a type shown in FIG. 2. It is to be noted that, the sputtering apparatus of FIG. 2 is shown by way of example, and a sputtering apparatus in which the manufacturing method of the invention is employed is not limited to the apparatus shown in FIG. 2.

As shown FIG. 2, a sputtering apparatus 1 includes a chamber 10 for creating a low-pressure environment (e.g., 1×10⁻⁵ Pa to 1 Pa), a holding portion 11 that holds an initial roll 30 in which an elongated film base is wound up, a guide roll 12 that guides the film base which is transported to a film formation roll described below, the guide roll 12 being disposed between the holding portion 11 and the film formation roll, a film formation roll 13 (first film formation roll) which is configured to be temperature controllable (e.g., 20° C. to 250° C.) and forms a first laminated body on one face of the film base, target materials 14, 15, 16 (first, second and third target materials) that are electrically connected to a direct-current power source, not shown, and that are each disposed so as to oppose the film formation roll 13, guide rolls 17a to 17d that are disposed in this order along a transport direction indicated by arrows in the figure and transport the film base, on which the first laminated body is formed, to the film formation roll described below, a film formation roll 18 (second film formation roll) which is configured to be temperature controllable (e.g., 20° C. to 250° C.) and forms a second laminated body on the other face of the film base, target materials 19, 20 (fourth and fifth target materials) that are electrically connected to a direct-current power source, not shown, and that are each disposed so as to oppose the film formation roll 18, a guide roll 21 that is disposed downstream of the film formation roll 18, and a holding portion 22 that holds a roll 31 obtained by winding up the film base on which the first and second laminated bodies are formed.

The chamber 10 has a transportation compartment 23 in which the initial roll 30 and the roll 31 that has been processed are held and from which the film base on which the first laminated body is formed is transported to the two processing compartments described below. Further, in order that a sputtering process can be performed under mutually different conditions using the target materials 14, 15 and 16, three processing compartments 24, 25 and 26 are provided around the film formation roll 13. Similarly, in order that a sputtering process can be performed under mutually different conditions using the target materials 19 and 20, two processing compartments 27 and 28 are provided around the film formation roll 18.

With such a sputtering apparatus, for example, a plasma is generated by applying a voltage (for example, −400 V to −100 V) across the film formation roll 13 and each target material or across the film formation roll 18 and each target material, a cation in the plasma is collided to a target material, which is a negative electrode, and a substance ejected from a surface of the aforementioned target material is deposited onto the film base.

The first laminated body obtained in step S12 can be manufactured by performing a sputtering process on the film base while transporting it along a peripheral surface of the film formation roll 13, with a target (e.g., a fired target containing indium oxide and tin oxide) that can form a transparent conductor layer being used as the target material 14, a metal target being used as the target material 15, and a metal oxide target being used as the target material 16.

The metal oxide membrane layer can also be formed while feeding an oxygen gas such that an oxygen partial pressure around the target material 16 is 1×10⁻⁴ Pa to 0.1 Pa, with a non-oxidized metal target being used as the target material 16, instead of the aforementioned metal oxide target.

A second laminated body B obtained in step S15 can be manufactured by performing a sputtering process on the film base on which the first laminated body is formed while transporting it along a peripheral surface of the film formation roll 18, with a target that can form a transparent conductor layer being used as the target material 19 and a metal target being used as the target material 20.

In the present invention, a second metal oxide membrane layer may be further laminated on the second metal layer by further providing another target material (sixth target material) downstream of the target material 20 in the transport direction.

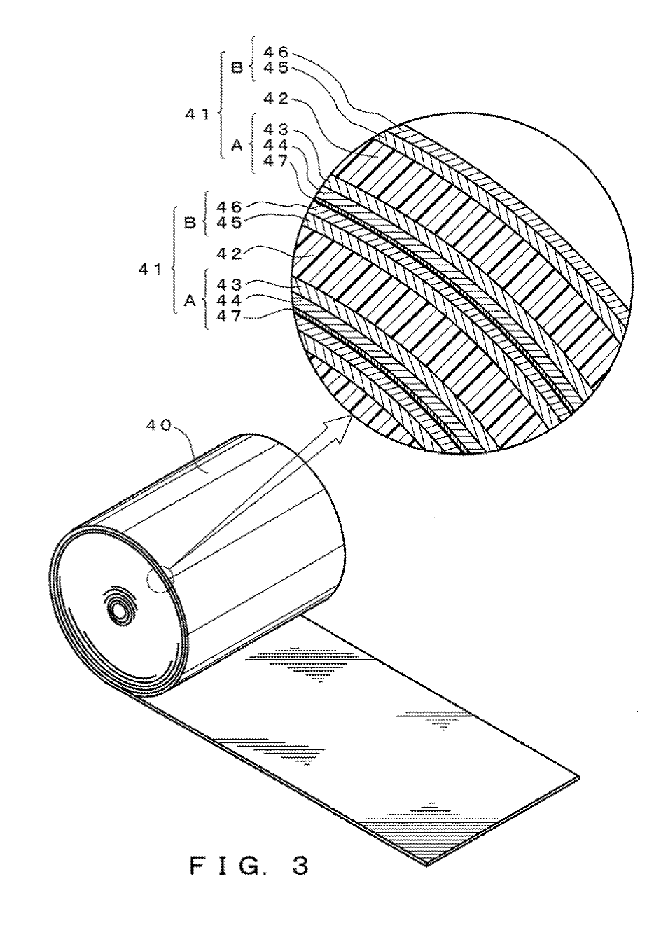

FIG. 3 is a perspective view showing an exemplary conductive film roll manufactured with the sputtering apparatus of FIG. 2. The conductive film roll obtained by the manufacturing method of the present invention is an elongated conductive film that is wound up in a roll.

As shown in FIG. 3, a conductive film 41 includes a film base 42, a transparent conductor layer (first transparent conductor layer) 43 formed on one side of the film base, a metal layer (first metal layer) 44 formed on a side of the transparent conductor layer 43 opposite the film base 42, a transparent conductor layer (second transparent conductor layer) 45 formed on the other side of the film base 42, a metal layer (second metal layer) 46 formed on a side of the transparent conductor layer 45 opposite the film base 42, and a metal oxide membrane layer 47 formed on a side of the metal layer 44 opposite the transparent conductor layer 43. The transparent conductor layer 43, the metal layer 44 and the metal oxide membrane layer 47 constitute a first laminated body A, and the transparent conductor layer 45 and the metal layer 46 constitute a second laminated body B. With the conductive film roll 40 made by winding up the conductive film 41, the oxide metal membrane layer 47 is interposed between the metal layer 44 and the metal layer 46.

The conductive film 41 has a length of typically 100 m or more, and preferably, 500 m to 5,000 m. At the center portion of the conductive film roll 40, normally, a core made of plastics or a metal on which the conductive film is wound up is disposed.

The film base 42 is preferably made of polyethylene terephthalate, polycycloolefin or polycarbonate, since these have an improved transparency and heat resistance. The film base 42 may have, on its surface, an easy adhesion layer (anchor coat layer) for increasing a bond strength between a transparent electrode pattern and the film base, a refractive index adjustment layer (index-matching layer) for adjusting a reflectivity of the film base or a hardcoat layer for increasing a surface hardness of the film base.

The transparent conductor layers 43, 45 are each a layer that has a high transmissivity (greater than or equal to 80%) in a visible light range (400 nm to 700 nm) and has a surface resistance value per unit area (Ω/□: Ohms per square) of less than or equal to 500 Ω/□. A material forming the transparent conductor layers 43, 45 is preferably an indium tin oxide, an indium zinc oxide or a composite oxide of indium oxide-zinc oxide. Each of the transparent conductor layer 43, 45 has a thickness of preferably 20 nm to 80 nm.

A material forming the metal layers 44, 46 is preferably copper, silver, aluminum, a copper alloy, a nickel alloy, a titanium alloy or a silver alloy, and more preferably, copper. A surface resistance value per unit area of each of the metal layer 44, 46 is preferably less than or equal to 10 Ω/□, and more preferably, 0.1 Ω/□ to 1 Ω/□. Concerning the ease of machining of the wiring, the thickness of each of the metal layer 44, 46 is preferably 20 nm to 300 nm.

The material forming the metal oxide membrane layer is preferably a metal oxide obtained by oxidizing the material forming the first metal layer, and more preferably a copper oxide. The thickness of the metal oxide membrane layer is, from a point of view of preventing the bonding, preferably 1 nm to 15 nm.

The conductive film roll may further include, on the second copper layer, a second metal oxide membrane layer which is similar to the one formed on the first copper layer.

As has been described above, according to the present embodiment, the film base 42 is transported while being made it into contact with the film formation roll 13 and the transparent conductor layer 43, the metal layer 44 and the metal oxide membrane layer 47 are sequentially laminated on the first face side of the film base 42 by sputtering to form the first laminated body A (first step). The film base, on which the first laminated body is formed, is fed to the film formation roll 18 without being wound up into a roll and transported while making the metal oxide membrane layer 47 of the first laminated body into contact with the film formation roll 18, and the transparent conductor layer 45 and the metal layer 46 are sequentially laminated on a second face side of the film base, on which the first laminated body is not formed, by sputtering, to form the second laminated body B (second step). According to the present method, when the conductive film is wound up into a roll, since the metal oxide membrane layer 47 is interposed between the metal layer 44 and the metal layer 46, the adjacent film surfaces will not bond to each other and a high quality can be maintained.

Hereinafter, examples of the invention will be described.

### EXAMPLES

### Example 1

A roll of film base made of a polycycloolefin film (manufactured by Zeon Corporation, product name: “ZEONOR” (registered trademark)) having a length of 1,000 m and a thickness of 100 μm was placed in a sputtering apparatus of FIG. 2. The film base was transported while being made it into contact with a first film formation roll, and a first transparent conductor layer made of an indium-tin oxide layer having a thickness of 20 nm, a first copper layer having a thickness of 50 nm, and a copper oxide membrane layer having a thickness of 2.5 nm were sequentially laminated by sputtering on a first face side of the film base which is not in contact with the first film formation roll to form a first laminated body.

Then, the first laminated body was fed to a second film formation roll without being wound up into a roll and transported while making a side of the first laminated body on which the copper oxide layer is formed into contact with the second film formation roll, and sequentially laminating a second transparent conductor layer made of an indium-tin oxide layer having a thickness of 20 nm and a second copper layer having a thickness of 50 nm by sputtering on a second face side of the film base on which the first laminated body is not formed to form a second laminated body (conductive film).

Subsequently, the second laminated body was wound up on a plastic core to manufacture a conductive film roll.

Then, the conductive film roll of Example 1 was measured and evaluated in the following manner.

(1) Measurement of Thickness of Metal Oxide Membrane Layer

Using an X-ray photoelectron spectroscopy analyzer device (manufactured by ULVAC-PHI, Inc, product name: “QuanteraSXM”), a thickness of the copper oxide layer was measured.

(2) Measurement of Thicknesses of Transparent Conductor Layer, Metal Layer and Film Base

The thicknesses of the transparent conductor layer, the copper layer and the film base were measured by carrying out a cross-section observation with a transmission electron microscope (manufactured by Hitachi, Ltd., product name: “H-7650”).

The thickness of the film base was measured with a film thickness meter (manufactured by Ozaki MFG. Co., Ltd., Peacock digital dial gauge DG-205).

(3) Bonding of Conductive Film Roll

Inspection was carried out by unwinding the conductive film from the conductive film roll and observing a roll surface.

By unwinding the conductive film roll of Example 1 and observing a roll surface, it was found that, during the unwinding, a peeling-off sound was not produced and a surface of the transparent conductor layer was even. In other words, bonding between the conductive film surfaces was not observed.

### Comparative Example 1

As a comparative example 1, a conductive film roll was manufactured in a manner similar to Example 1 except that the copper oxide layer was not formed.

By unwinding this conductive film roll and observing a roll surface, it was found that, during the unwinding, a peeling-off sound was produced and numerous flaws were produced in a surface of the transparent conductor layer, and bonding between the conductive film surfaces was observed.

Therefore, in the manufacturing method of the invention, by feeding the film base, on which the first laminated body including a copper oxide layer is formed, to a second film formation roll without being wound up to form a second laminated body on a side of the film base on which the first laminated body is not formed, it was found that adjacent film surfaces are not bonded and can maintain a high quality.

### INDUSTRIAL APPLICABILITY

With a conductive film roll obtained by the manufacturing method of the invention, preferably, the unwound conductive film is cut into a display size and used in touch sensors of a capacitive type or the like.

What is claimed is:

1. A method of manufacturing a conductive film roll, comprising:
a first step of transporting a film base having an elongated shape while making it into contact with a first film formation roll and sequentially laminating a first transparent conductor layer, a first metal layer and a metal oxide membrane layer by sputtering on a first face side of the film base to form a first laminated body;
a second step of feeding the film base, on which the first laminated body is formed, to a second film formation roll without winding it up, transporting the film base while making the metal oxide membrane layer of the first laminated body into contact with the second film formation roll, and sequentially laminating a second transparent conductor layer and a second metal layer by sputtering on a second face side of the film base on which the first laminated body is not formed to form a second laminated body; and
a third step of winding up the second laminated body into a roll.

2. The method of manufacturing a conductive film roll according to claim 1, wherein, in the first step, the metal oxide membrane layer having a thickness of 1 nm to 15 nm is formed.

3. The method of manufacturing a conductive film roll according to claim 1, wherein the first metal layer and the second metal layer are made of a material selected from a group consisting of copper, silver, aluminum, copper alloy, nickel alloy, titanium alloy and silver alloy.

4. The method of manufacturing a conductive film roll according to claim 1, wherein the metal oxide membrane layer is made of an oxide of a material selected from a group consisting of copper, silver, aluminum, copper alloy, nickel alloy, titanium alloy and silver alloy.
